(19) United States
(12) Patent Application Publication
(10) Pub. No.: US 2026/0333664 A1
(43) Pub. Date: Oct. 22, 2026

(54) METHOD FOR FORMING CELL CONTACT OF MEMORY DEVICE

(71) Applicant: Micron Technology, Inc., Boise, ID (US)

(72) Inventor: Rieko Satoh, Higashihiroshima-shi (JP)

(21) Appl. No.: 19/578,472

(22) Filed: Mar. 25, 2026

Related U.S. Application Data
(60) Provisional application No. 63/780,691, filed on Mar. 31, 2025.

(51) Int. Cl. H10B 12/00

(52) U.S. Cl. CPC H10B 12/0335; H10B 12/09; H10B 12/315; H10B 12/485; H10B 12/50

(57) ABSTRACT

Embodiments of the disclosure provide a method for forming a cell contact of a memory cell, the method comprising providing a first oxide film and a second oxide film on a semiconductor substrate in a memory cell array region and a dummy region and removing a part of the second oxide film in the dummy region, wherein the part is to be under a photoresist at a later process of wet etching as part of forming a cell contact. The method further comprises filling the removed part of the second oxide film with a nitride and providing the photoresist on the nitride-filled part, and further comprises removing the first and second oxide films by the wet etching in the memory cell array region. The method can prevent the wet etching outside of the memory cell array region and keep the dummy region intact without being affected by the wet etching.

### CROSS-REFERENCE TO RELATED APPLICATIONS

This application claims the filing benefit of U.S. Provisional Application No. 63/780,691, filed Mar. 31, 2025. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines and bit lines. Each memory cell may include a capacitor to store data and a transistor to access the capacitor. A memory cell capacitor may be coupled to one of source and drain of an associated memory cell transistor formed in active regions of a semiconductor substrate by a cell contact and a redistribution layer (RDL). A cell contact may be a conductive contact that is coupled to one of source/drain regions in the semiconductor substrate at one end and to an RDL at another end. The RDL is further coupled to an associated memory cell capacitor. The cell contact may thus be formed to couple the cell capacitor to the one of the source/drain regions in the semiconductor substrate via the corresponding RDL.

### BRIEF DESCRIPTION OF THE DRAWINGS

FIGS. 1A-1T depict processes of an example method of forming at least part of a memory device including a cell contact in a cross-sectional view according to some embodiments of the disclosure.

FIG. 2 A depicts an example layout of memory mats in a memory device in a plan view, and FIG. 2 B depicts an example memory mat in an enlarged view, according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

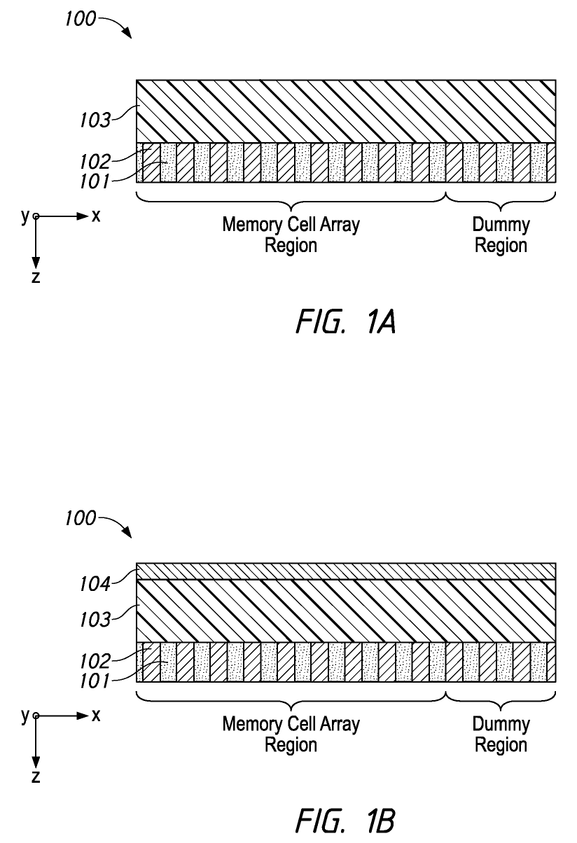

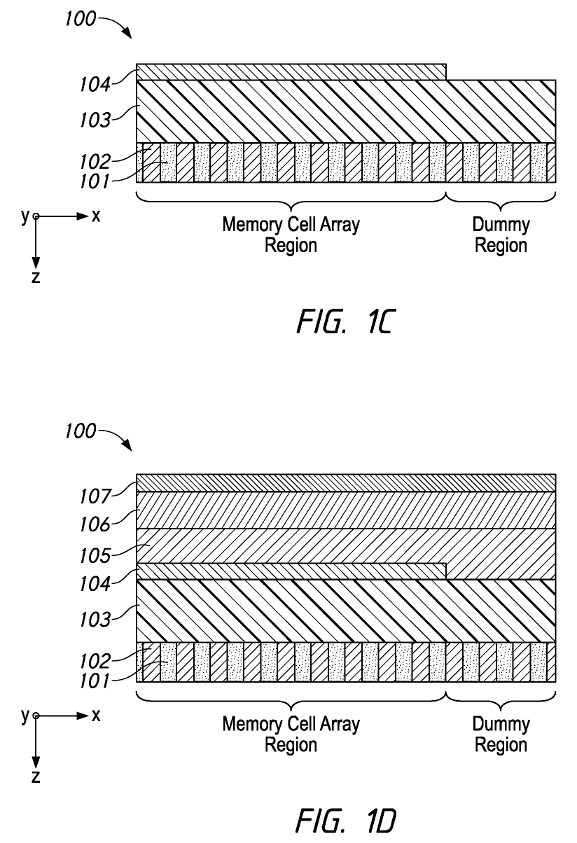

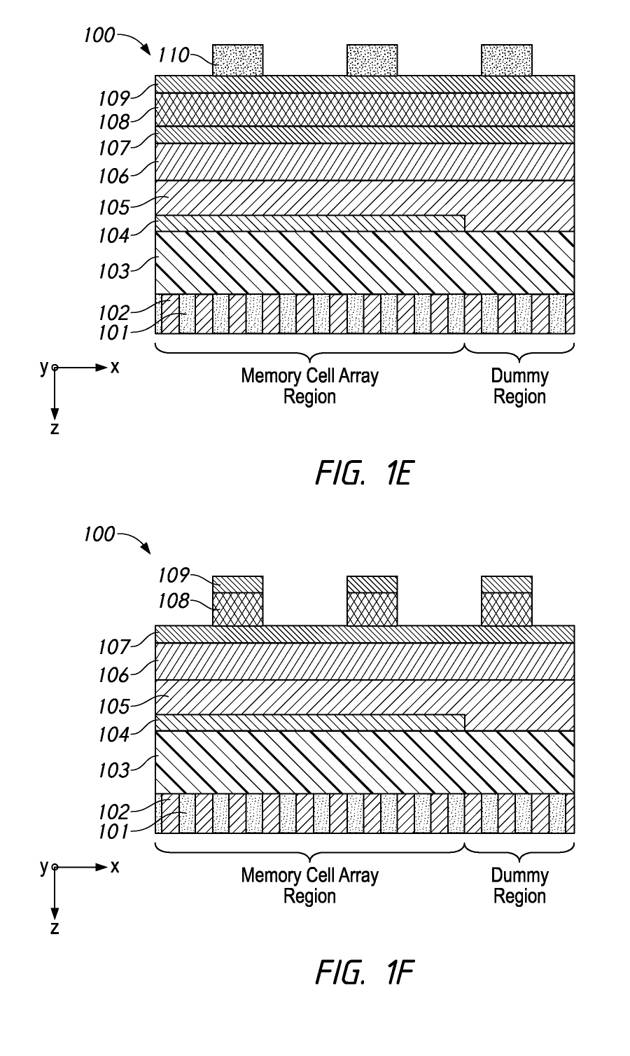

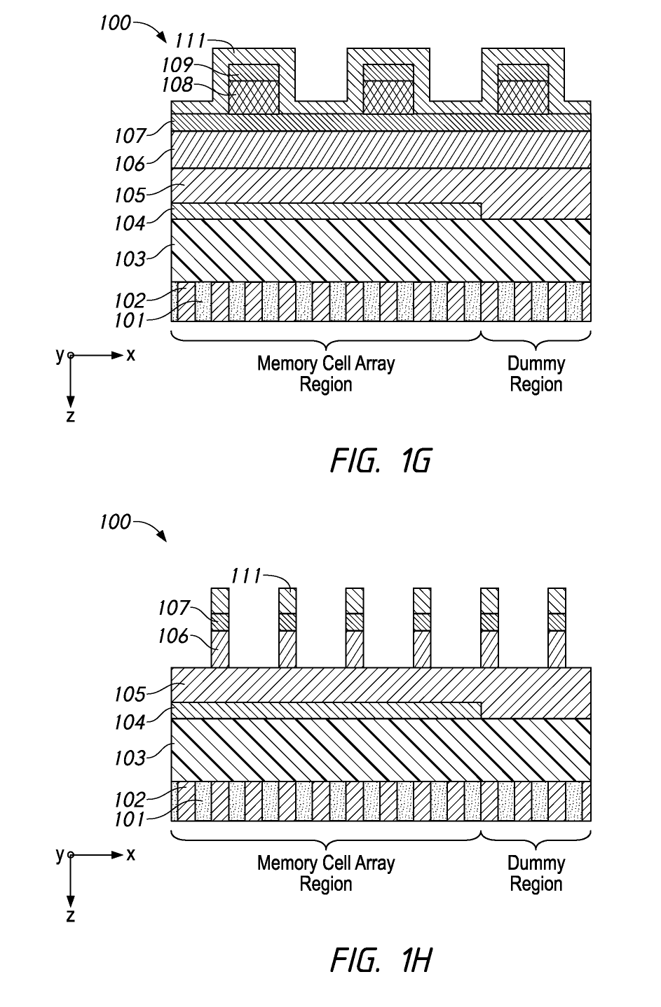

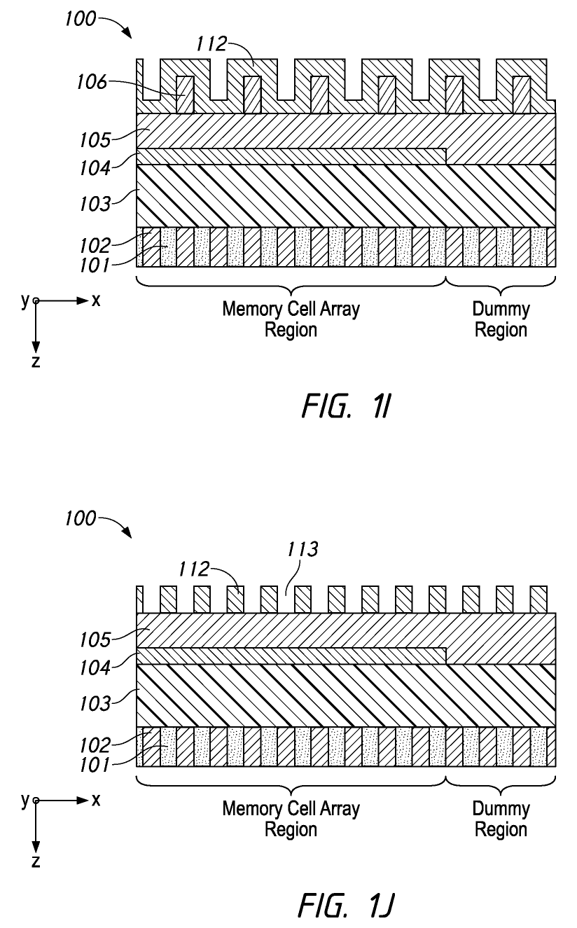

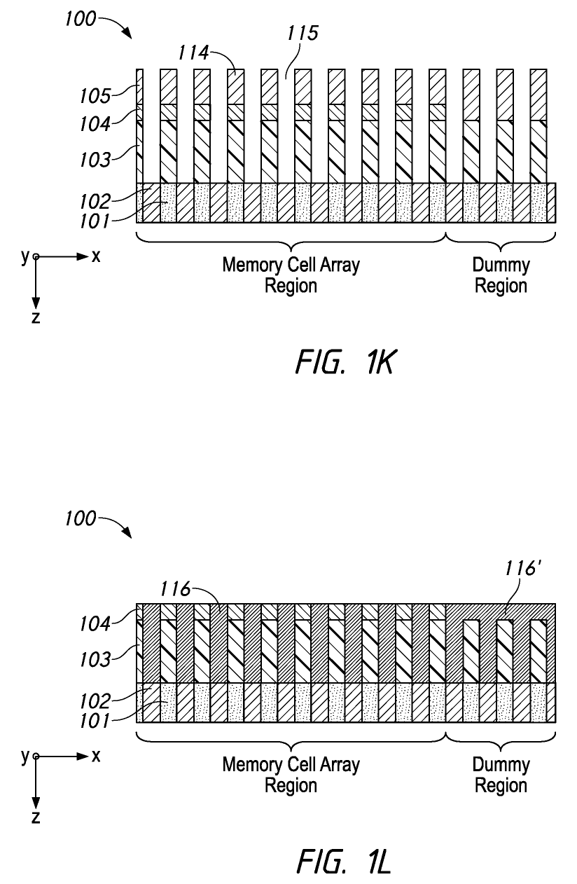

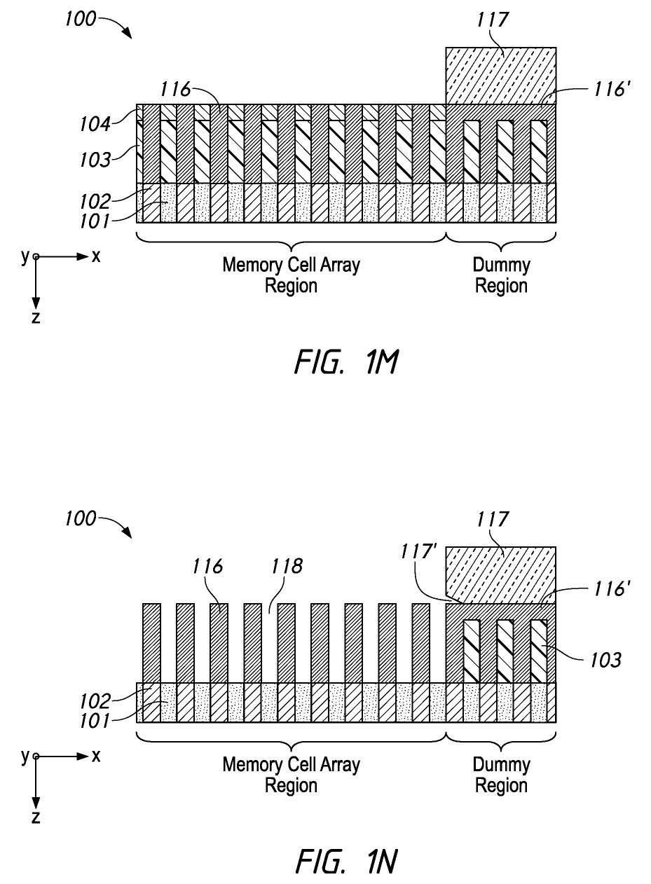

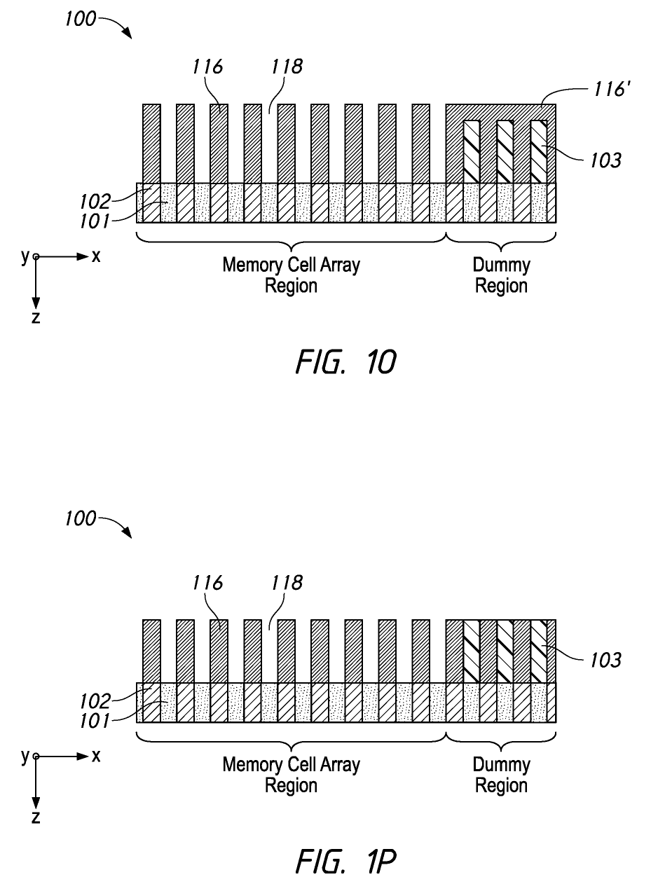

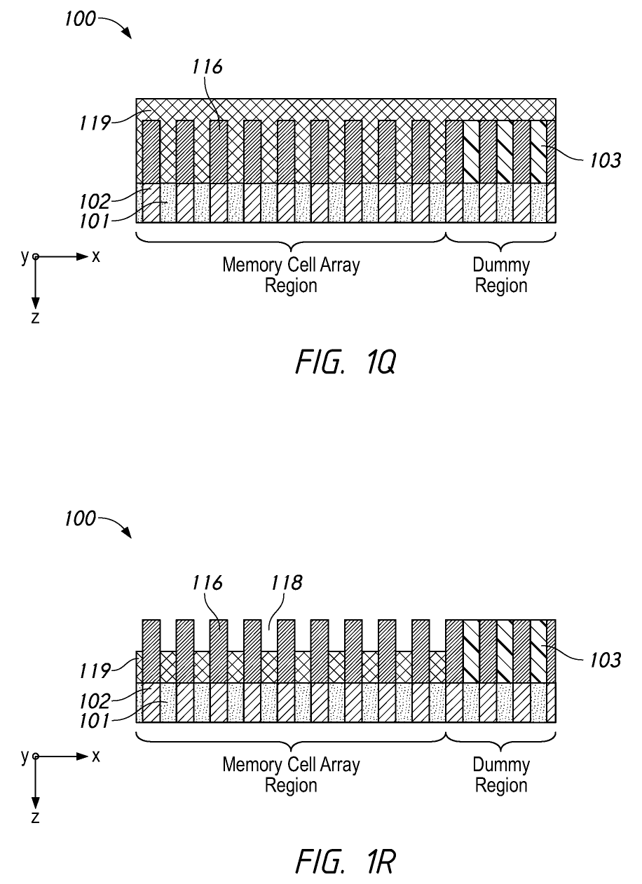

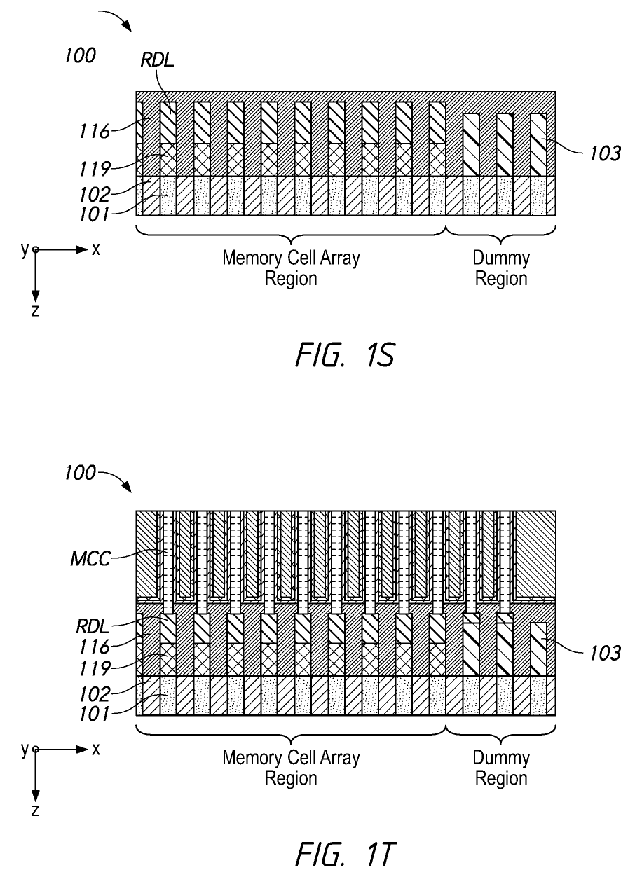

FIGS. 1A-1T depict processes of an example method of forming at least part of a memory device 100 including a cell contact in a cross-sectional view according to some embodiments of the disclosure. The memory device 100 may be a dynamic random-access memory (DRAM). The memory device 100 may be one example of a semiconductor device. The memory device 100 may be one example of an apparatus. The memory device 100 includes a memory cell array region and a peripheral region (not separately depicted) on a semiconductor substrate 101, such as a silicon substrate. The memory device 100 also includes a dummy region between the memory cell array region and the peripheral region. In some instances, the dummy region may be part of the memory cell array region. In some instances, the dummy region may be part of the peripheral region.

The memory cell array region may include a plurality of memory cells arranged at intersections of word lines 102 and bit lines (not separately depicted). Word lines 102 may be arranged in parallel with each other in a first horizontal direction, which may be for example an X-axis direction in the drawing, and each may extend in a second horizontal direction, which may be for example a Y-axis direction in the drawing, perpendicular (or substantially perpendicular within reasonable tolerances of fabrication, measurement, etc.) to the first horizontal direction. Bit lines may be arranged in parallel with each other in the Y-axis direction and each may extend in the X-axis direction. The memory cell array region may also include cell contacts that are coupled to active regions, such as source and drain regions, formed in the semiconductor substrate 101. The depicted example shows at least part of the active regions of the semiconductor substrate 101. The memory cell array region may further include redistribution layers RDL above the corresponding cell contacts and memory cell capacitors MCC above the corresponding redistribution layers RDL (see RDL and MCC in FIG. 1T, for example). The cell contacts couple the active regions of the semiconductor substrate 101 to the redistribution layers RDL. The redistribution layers RDL couple the cell contacts to the memory cell capacitors MCC. The active regions of the semiconductor substrate 101 and the memory cell capacitors MCC are thus coupled to each other by the cell contacts and the redistribution layers RDL. The cell contacts are formed in the memory cell array region to couple the memory cell capacitors MCC to the active (source/drain) regions of the semiconductor substrate 101 via the redistribution layers RDL. The memory cell array region may include other elements as appropriate. The memory cell array region may have a square shape, a rectangular shape, or the like in a plan view (for example, in a plane along the X-axis direction and the Y-axis direction) on the semiconductor substrate 101. The peripheral region may be provided adjacent to the memory cell array region in the X-axis direction and/or the Y-axis direction. The peripheral region may be provided around the memory cell array region in the plan view on the semiconductor substrate 101. The dummy region may be located between the memory cell array region and the peripheral region. The dummy region may be arranged adjacent to and surrounding the memory cell array region. The peripheral region may then be positioned next to the dummy region. The memory cell array region includes active memory cells, whereas the dummy region includes dummy memory cells. Unlike the active memory cells, the dummy memory cells do not have the ability to store data or to be used during the write and read operations. In some instances, the dummy region may not have cell contacts for coupling the dummy memory cells to active regions of the semiconductor substrate.

As shown in FIG. 1A, a first oxide film 103 is provided on the semiconductor substrate 101 in the memory cell array region and the dummy region. The semiconductor substrate 101 may include active regions, such as source/drain regions and lightly doped drain (LDD) regions. In the depicted example, the semiconductor substrate 101 further includes a part of each of word lines 102. The depicted part of each word line 102 may include a nitride. The first oxide film 103 may include, for example, spin-on dielectric (SOD). The first oxide film 103 may be continuous in the X-axis and Y-axis directions over the memory cell array and dummy regions. The first oxide film 103 may be formed by for example oxide deposition. Any conventional processes as well as conventional oxide materials may be applicable as appropriate. A top surface of the first oxide film 103 may be smoothed and cleaned by for example chemical-mechanical polishing (CMP).

As shown in FIG. 1B, a second oxide film 104 is provided on the first oxide film 103. The second oxide film 104 may include, for example, tetraethyl orthosilicate (TEOS). The second oxide film 104 may be continuous in the X-axis and Y-axis directions over the memory cell array and dummy regions. The second oxide film 104 may be formed by for example oxide deposition. Any conventional processes as well as conventional oxide materials may be applicable as appropriate. An oxide of the first oxide film 103 (such as SOD) and an oxide of the second oxide film 104 (such as TEOS) may be different. A top surface of the second oxide film 104 may be smoothed and cleaned by for example chemical-mechanical polishing (CMP).

As shown in FIG. 1C, a part of the second oxide film 104 in the dummy region is removed. The part removed is a part to be under a photoresist (which will be described in more detail below with reference to, for example, FIGS. 1M and 1N) configured to cover an area that is not to be etched at a later process in the dummy region. For example, the part of the second oxide film 104 to be removed is determined in advance based on which part will be under the photoresist that protects the area from etching during the later process of forming cell contacts. The part may be removed by for example photolithography and dry etching. Any conventional processes including but not limited to photolithography and dry etching may be applicable as appropriate.

As shown in FIG. 1D, as part of cell contact processes, multiple layers and/or films, such as a polysilicon layer 105, a carbon layer 106, and an anti-reflective coating (ARC) film 107, are provided in the memory cell array region and the dummy region by for example deposition. Any conventional processes as well as conventional materials may be applicable to form the multiple layers and/or films as appropriate. In the depicted example, the removed part of the second oxide film 104 is filled with poly-Si of the polysilicon layer 105.

As shown in FIG. 1E, further layers, such as an underling layer 108 and a hard mask 109, may be provided in the memory cell array region and the dummy region by for example deposition. The underling layer 108 may include for example carbon. Any conventional processes as well as conventional materials may be applicable to form the further layers as appropriate. The multiple layers provided on the first and second oxide layers 103 and 104 in the memory cell array and dummy regions are not limited to the depicted examples. The multiple layers may omit one or more of the layers/films illustrated or include other layers/films as appropriate. Subsequently, as part of patterning cell contacts, a photoresist 110 is provided on a top layer of the multiple layers to cover a part that is not to be etched at the next process. The photoresist 110 may form a line-and-space pattern.

As shown in FIG. 1F, a part of the underlying layer 108 and the hard mask 109 that is not covered by the photoresist 110 is removed by for example photolithography and dry etching in the memory cell array region and the dummy region. Any conventional processes including but not limited to photolithography and dry etching may be applicable as appropriate. The remaining part of the underlying layer 108 and the hard mask 109 under the photoresist 110 may form a line-and-space pattern corresponding to that of the photoresist 110, each line extending in the Y-axis direction in the drawing. The photoresist 110 is also removed.

As shown in FIG. 1G, another oxide film 111 is provided on the exposed top and side surfaces of the remaining part of the underlying layer 108 and the hard mask 109 and also the exposed top surfaces of the ARC film 107. The oxide film 111 may be formed by for example oxide deposition. Any conventional processes as well as conventional oxide materials may be applicable as appropriate. The oxide film 111 may be a spacer oxide film that may be used to define openings (which will be described in more detail below with reference to for example FIG. 1K) for cell contact patterning. In the present embodiments, the cell contact patterning may include double patterning. In other embodiments, the cell contact patterning may include multiple patterning.

As shown in FIG. 1H, a top part of the oxide film 111 on each line of the underlying layer 108 and the hard mask 109 and a bottom part of the oxide film 111 between the neighboring lines of the underlying layer 108 and the hard mask 109 are removed by for example dry etching. Furthermore, the underlying layer 108 and the hard mask 109 are removed. Still furthermore, a part of the ARC film 107 and the carbon layer 106 is removed. In the depicted example, this process leaves only a part of the oxide film 111, the ARC film 107 and the carbon layer 106 on the polysilicon film 105 at a position corresponding to every other word line 102. The remaining part forms a line-and-space pattern, each line extending in the Y-axis direction in the drawing. Any conventional processes including but not limited to etching may be applicable to remove the target parts/portions and elements and form the desired pattern as appropriate.

As shown in FIG. 1I, the remaining part of the oxide film 111 and the ARC film 107 is first removed by for example wet etching while leaving the carbon layer 106 in the line-and-space pattern. Any conventional processes as well as conventional materials such as wet etching chemicals may be applicable as appropriate. Subsequently, still another oxide film 112 is provided on the carbon layer 106 by for example oxide deposition. Any conventional processes as well as conventional oxide materials may be applicable as appropriate. The oxide film 112 may be a second spacer oxide film that may define openings for cell contact patterning.

As shown FIG. 1J, a top part of the oxide film 112 on each line of the carbon layer 106 and a bottom part of the oxide film 112 between the neighboring lines of the carbon layer 106 are removed by for example dry etching. In the depicted example, this process leaves only a part of the oxide film 112 adjacent to the carbon layer 106 on both sides thereof in the X-axis direction in the drawing. The remaining part of the oxide film 112 forms a second line-and-space pattern, each line extending in the Y-axis direction in the drawing with each space 113 also extending in the Y-axis direction between the neighboring lines. The position of each line corresponds to the position of the active region of the semiconductor substrate 101, which will correspond to a position of an opening for each cell contact at a later process (see for example FIGS. 1N-1R). Any conventional processes including but not limited to etching may be applicable to remove the target parts/portions and elements and form the desired pattern as appropriate.

As shown in FIG. 1K, a part of the polysilicon film 105, the second oxide film 104 and the first oxide film 103 at each space 113 is removed by for example dry etching, and the oxide film 112 is also removed by for example subsequent dry etching. This process leaves a part 114 of the polysilicon film 105, the second oxide film 104 and the first oxide film 103 under the removed line of the oxide film 112 on the semiconductor substrate 101 and forms an opening 115 at the position corresponding to each word line 102. The opening 115 may have a slot-like shape with a narrow aperture or a slit. The remaining part 114 and the opening 115 form a line-and-space pattern having a pitch equal (or substantially equal within reasonable tolerances of fabrication, measurement, etc.) to a pitch of a cell contact which is formed at a later process (see for example FIGS. 1N-1R). Any conventional processes including but not limited to etching may be applicable to remove the target parts/portions and elements and form the desired pattern as appropriate.

As shown in FIG. 1L, the polysilicon film 105 of the part 114 is removed by for example dry etching, and subsequently each opening 115 is filled with a nitride 116 by for example deposition. At this time, the part of the second oxide film 104 that was removed and filled with the polysilicon film 105 in the dummy region at the previous process (see FIGS. 1C and 1D) is revealed by removing the polysilicon film 105 and is filed with the nitride, which is denoted as 116’ in the drawing. The nitride 116, 116’ may be smoothed and cleaned by for example CMP. The nitride 116 provided in the openings 115 form lines (which may also be referred to as bars or rails) each extending in the Y-axis direction and will isolate neighboring cell contacts from each other in the X-axis direction (see for example FIGS. 1N-1R). Any conventional processes and conventional nitride materials may be applicable to form the desired pattern as appropriate.

As shown in FIG. 1M, a photoresist 117 is provided in the dummy region. More specifically, the photoresist 117 is provided on the nitride 116’ to cover the area that should not be etched at a later process in the dummy region. In some instances, the photoresist 117 may also be provided in the peripheral region next to the dummy region.

Subsequently, as shown in FIG. 1N, the second oxide film 104 and the first oxide film 103 in the memory cell array region are removed by wet etching. Any conventional wet etching processes as well as conventional wet etching chemicals may be applicable as appropriate. During the wet etching process, a wet etching chemical may penetrate into and damage a part of the photoresist 117 at for example a border between the memory cell array region and the dummy region, possibly leaving an impaired part 117’ at or near a bottom of the photoresist 117. However, according to the present embodiments, even if the photoresist 117 is damaged, since the nitride 116’ is provided under the photoresist 117, the oxide films 103 and 104 under the photoresist 117 and hence under the nitride 116’ in the dummy region will not be affected by the wet etching process. Therefore, the present embodiments effectively prevent wet etching outside of the memory cell array region and keep the dummy region intact. The remaining nitride 116 in the memory cell array region forms a line-and-space pattern including a space 118 between the neighboring nitride lines 116. The nitride lines (or bars or rails) 116 are positioned at the corresponding word lines 112, and the spaces 118 are positioned at the corresponding active regions of the semiconductor substrate 101. Due to the nitride 116’ under the photoresist 117, the first oxide film 103 remains unetched in the dummy region.

Subsequently, as shown in FIGS. 1O and 1P, the photoresist 117 is removed, and a top part of the nitride 116 in the memory cell array region as well as the nitride 116’ in the dummy region are removed by for example dry etching. Any conventional processes to remove the target parts/portions and elements may be applicable as appropriate.

Finally, as shown in FIGS. 1Q and 1R, polycrystalline silicon or polysilicon 119 is provided by for example deposition, filling the openings 118 between the neighboring nitride lines 116, and the polysilicon 119 is then partially removed by for example dry etching to form cell contacts or at least part of cell contacts in the openings 118. The polysilicon cell contacts 119 are formed coupling to the active regions of the semiconductor substrate 101. In the resultant structure on the semiconductor substrate 101, the nitride lines 116 isolate the neighboring polysilicon cell contacts 119 from each other in the X-axis direction in the drawing in the memory cell array region. At this time, at least the part of the dummy region adjacent to the memory cell array region does not have any openings between the neighboring nitride lines 116 where the first oxide film 103 remains unlike the memory cell array region which has the openings 118. Therefore, the polysilicon 119 does not remain in the dummy region, and hence the cell contacts are not formed in the dummy region. The dummy region may thus provide dummy patterns that do not function for data storage unlike the active memory cells in the memory cell array region. In other embodiments, each of the cell contacts in the memory cell array region may include additional layers, films or the like, such as barrier metals and contact metals, besides the polysilicon portion as appropriate.

After the cell contacts are formed as described above, as shown in FIGS. 1S and 1T, redistribution layers RDL and memory cell capacitors MCC are formed in the memory cell array region and the dummy region. Any conventional processes and materials may be applicable to form the redistribution layers RDL and the memory cell capacitors MCC as appropriate. In the memory cell array region, the redistribution layers RDL are formed to couple the cell contacts 119 to the corresponding memory cell capacitors MCC. The redistribution layers RDL are coupled to the cell contacts 119 and the memory cell capacitors MCC at upper ends and lower ends, respectively. The redistribution layers RDL may include a conductive material, such as tungsten (W). The memory cell capacitors MCC may include a conductive material, such as titanium nitride (TiN). The memory cell capacitors MCC may have high-k films, insulating layers, and such, on side surfaces thereof as appropriate. Each memory cell capacitor MCC may have a vertical capacitor configuration that extends in a vertical direction (e.g., a Z-axis direction in the drawing). In the resultant structure, the memory cell capacitors MCC are coupled to the active regions of the semiconductor substrate 101 by the associated cell contacts and redistribution layers. In the dummy region, the redistribution layers RDL are formed on the corresponding oxide films 103, and the memory cell capacitors MCC are formed and coupled to the corresponding redistribution layers RDL. Since the dummy region does not include the cell contacts, the memory cell capacitors MCC are not coupled to the active regions of the semiconductor substrate 101, thus serving as dummy cell capacitors.

Accordingly, the present embodiments provide methods that can form a cell contact only in the memory cell array region in a further efficient manner, which is not substantially affected by a wet etching process of an oxide film on the semiconductor substrate after provision of a photoresist to cover an area in the dummy region that is not to be etched. The methods can effectively prevent wet etching outside of the memory cell array region and keep the dummy region intact. Furthermore, since damages to the dummy region during the oxide film wet etching of the memory cell array region can be prevented or mitigated, the number of dummy patterns, dummy cells, or the like in the dummy region can be reduced, which can lead to improvement of array efficiency on a chip or a die.

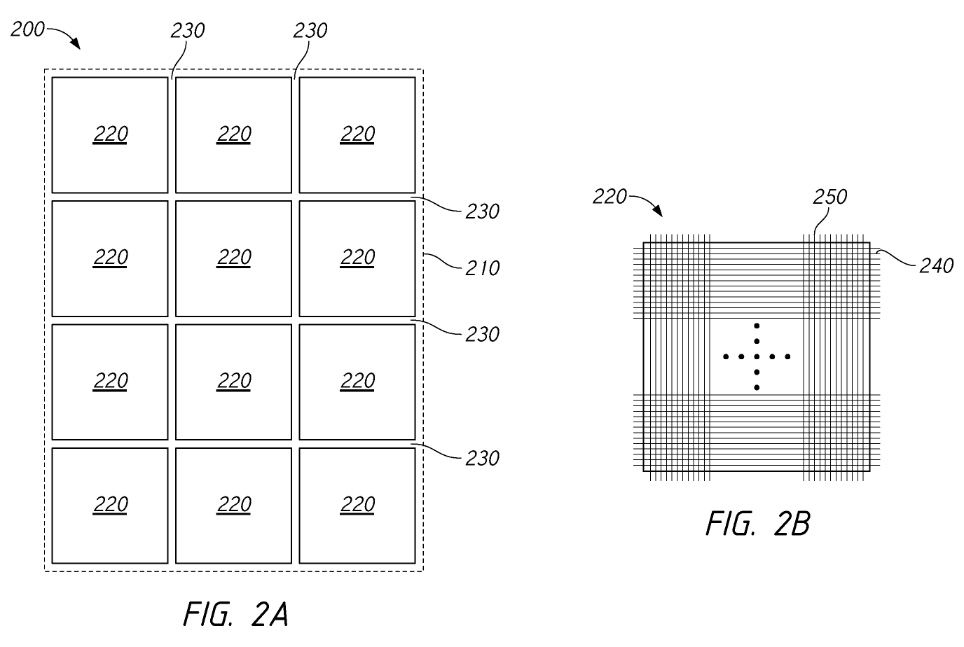

FIG. 2A depicts an example layout of memory mats 220 in a memory device 200 in a plan view according to some embodiments of the disclosure. FIG. 2B depicts an example memory mat 220 in an enlarged view according to some embodiments of the disclosure. The memory device 200 may be one example of a semiconductor device. The memory device 200 may be one example of an apparatus. The memory device 200 may be a DRAM. At least part of the memory device 200 may correspond to the memory device 100 of FIGS. 1A-1T. The memory device 200 includes a plurality of memory mats 220 arranged in matrix on a semiconductor substrate 210. Each memory mat 220 includes a plurality of word lines 240 and a plurality of bit lines 250 in a memory cell array region. Word lines 240 are arranged in rows. Bit lines 250 are arranged in columns. The word lines 240 and the bit lines 250 are orthogonal to each other. Each memory mat 220 include a plurality of memory cells at intersections of the word lines 240 (rows) and the bit lines 250 (columns) A direction parallel to the word lines 240 may be referred to as a word-line direction. A direction parallel to the bit lines 250 may be referred to as a bit-line direction. The word lines 240 and the bit lines 250 extend through the memory mat 220 into a peripheral region 230 adjacent to the memory cell array region in the word-line direction and the bit-line direction, respectively. The peripheral region 230 may surround the memory mat 220 or the memory cell array region. In the peripheral region in the word-line direction, the word lines 240 may be coupled to peripheral circuits, such as a row decoder. For example, at the time of reading data from or writing data to a memory cell, a selected row address may be input to a row decoder from a row address buffer, and a corresponding word line may control access to one or more corresponding memory cells. In the peripheral region in the bit-line direction, the bit lines 250 may be coupled to other peripheral circuits, such as a column decoder. For example, at the time of data read or data write, a selected column address may be input to a column decoder from a column address buffer, and a corresponding bit line may control access to one or more corresponding memory cells. Each memory mat 220 may also include a dummy region between the memory cell array region and the peripheral region. The dummy portion may surround the memory cell portion. While the memory cell array region includes active cell structures, the dummy region may include dummy cell structures. For example, the dummy region may not include cell contacts and/or redistribution layers that couple cell capacitors to active regions of the semiconductor substrate. The cell capacitors in the dummy region do not function as active cell capacitors, unlike those in the memory cell array region. In some instances, the dummy region may be part of the memory cell array region. In other instances, the dummy region may be part of the peripheral region. The memory cell array region and the dummy region may correspond to the memory cell array region and the dummy region of FIGS. 1A-1T, respectively.

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. A method, comprising:
providing a first oxide film on a semiconductor substrate in a memory cell array region and a dummy region;
providing a second oxide film on the first oxide film in the memory cell array region and the dummy region; and
removing a part of the second oxide film in the dummy region, wherein the part is to be under a photoresist configured to cover an area that is not to be etched at a later process of wet etching as part of forming a cell contact.

2. The method according to claim 1, further comprising providing a polysilicon layer on the second oxide film in the memory cell array region and the dummy region and filling the removed part of the second oxide film with the polysilicon layer.

3. The method according to claim 1, further comprising:
forming a plurality of first openings in the first and second oxide films;
filling the plurality of first openings with a nitride to form a plurality of cell contact spacers;
filling the removed part of the second oxide film with the nitride;
providing the photoresist on the removed part filled with the nitride; and
removing the first and second oxide films by the wet etching in an area not covered by the photoresist to form a plurality of second openings between neighboring cell contact spacers of the plurality of cell contact spacers, while leaving the first oxide film in an area covered by the photoresist.

4. The method according to claim 3, further comprising:
removing the photoresist; and
providing polysilicon in each of the plurality of second openings as at least part of the cell contact in the area not covered by the photoresist.

5. The method according to claim 4, further comprising removing part of the nitride to shape the plurality of cell contact spacers before providing the polysilicon.

6. The method according to claim 5, wherein removing the part of the nitride includes removing the nitride from the removed part of the second oxide film.

7. The method according to claim 4, wherein the part of the cell contact reaches an active region in the semiconductor substrate.

8. The method according to claim 4, wherein the cell contact spacers isolate neighboring cell contacts from each other.

9. The method according to claim 1, wherein removing the part of the second oxide film includes photolithography and/or dry etching.

10. The method according to claim 1, wherein the first oxide film includes spin-on dielectric (SOD).

11. The method according to claim 1, wherein the second oxide film includes tetraethyl orthosilicate (TEOS).

12. A method for forming at least part of a memory device, comprising:
providing a first oxide film on a semiconductor substrate in a memory cell array region and a dummy region of the memory device;
providing a second oxide film on the first oxide film;
removing at least a part of the second oxide film in the dummy region and filling the removed part with a polysilicon layer, wherein the part is adjacent to the memory cell array region;
forming a plurality of first openings in the first and second oxide films through the polysilicon layer in the memory cell array region and the dummy region;
after removing the polysilicon layer, filling with a nitride the plurality of first openings in both the memory cell array region and the dummy region and the removed part of the second oxide film in the dummy region, wherein a plurality of cell contact spacers are formed in the plurality of first openings;
providing the photoresist at least on the nitride-filled part in the dummy region;
removing the first and second oxide films by wet etching in the memory cell array region to form a plurality of second openings between neighboring cell contact spacers of the plurality of cell contact spacers;
removing the photoresist on the nitride-filled part in the dummy region; and
providing polysilicon in each of the plurality of second openings as at least part of cell contact in the memory cell array region.

13. The method according to claim 12, further comprising removing the nitride in the dummy region prior to providing the polysilicon.

14. The method according to claim 12, further comprising providing a redistribution layer coupled to the cell contact in the memory cell array region.

15. The method according to claim 14,further comprising providing a memory cell capacitor coupled to the redistribution layer in the memory cell array region.

16. The method according to claim 15, wherein the cell contact and the redistribution layer couple the memory cell capacitor to active regions of the semiconductor substrate.

17. The method according to claim 12, wherein the removed part of the second oxide in the dummy region includes at least a part to be under the photoresist during the wet etching.

18. The method according to claim 12, wherein the first oxide film includes spin-on dielectric (SOD), and the second oxide film includes tetraethyl orthosilicate (TEOS).

19. A method, comprising:
providing a first oxide film on a semiconductor substrate in a memory cell array region and a dummy region adjacent to the memory cell array region;
providing a second oxide film on the first oxide film in the memory cell array region and the dummy region;
removing a part of the second oxide film in the dummy region which is to be covered by a photoresist at a later process;
filling the removed part of the second oxide film with polysilicon in the dummy region;
forming a line-and-space pattern in the first and second oxide film in the memory cell array region and the dummy region;
removing the polysilicon from the removed part of the second oxide film in the dummy region;
filling a plurality of spaces of the line-and-space pattern and the removed part of the second oxide film with a nitride;
providing the photoresist on the removed part of the second oxide film;
removing by wet etching the first and second oxide films in the memory cell array region not covered by the photoresist to form a plurality of openings;
removing the photoresist; and
providing polysilicon in the plurality of openings to form a plurality of cell contacts in the memory cell array region.

20. The method according to claim 19, further comprising forming redistribution layers coupled to the cell contacts and forming cell capacitors coupled to the redistribution layers.
